(19) United States
(12) Patent Application Publication
(10) Pub. No.: US 2025/0118671 A1
(43) Pub. Date: Apr. 10, 2025

(54) SEMICONDUCTOR DEVICE

(71) Applicant: SAMSUNG ELECTRONICS CO., LTD., Suwon-si (KR)

(72) Inventors: Su Hyun Bark, Suwon-si (KR); Jun Sung Kim, Suwon-si (KR); Kyeong Beom Park, Suwon-si (KR); Jong Min Baek, Suwon-si (KR)

(73) Assignee: SAMSUNG ELECTRONICS CO., LTD., Suwon-si (KR)

(21) Appl. No.: 18/643,761

(22) Filed: Apr. 23, 2024

(30) Foreign Application Priority Data
Oct. 4, 2023 (KR) 10-2023-0131838

(51) Int. Cl. H01L 23/528; H01L 21/768; H01L 23/522; H01L 23/532

(52) U.S. Cl. CPC H01L 23/5283; H01L 21/76829; H01L 23/5226; H01L 23/53209

(57) ABSTRACT

A semiconductor device includes a substrate; an interlayer insulating layer disposed on the substrate; an upper wiring trench disposed in the interlayer insulating layer; and an upper wiring layer including: an upper wiring barrier layer disposed along a sidewall and a bottom surface of the upper wiring trench, an upper wiring filling layer disposed on the upper wiring barrier layer so as to fill at least a portion of an inside of the upper wiring trench, and an upper wiring capping layer disposed on an upper surface of the upper wiring filling layer, wherein the upper wiring capping layer includes cobalt (Co), and wherein a volume percentage of a crystal structure having a hexagonal close-packed structure included in the upper wiring capping layer is in a range of about 80% to about 100%.

### CROSS-REFERENCE TO RELATED APPLICATION

This application is based on and claims priority under 35 U.S.C. § 119 to Korean Patent Application No. 10-2023-0131838, filed on Oct. 4, 2023, in the Korean Intellectual Property Office, the disclosure of which is incorporated by reference herein in its entirety.

### BACKGROUND

### 1. Field

The disclosure relates to a semiconductor device.

### 2. Description of Related Art

Under development of electronic technology, down-scaling of a semiconductor device has recently progressed rapidly, thereby requiring high integration and low power consumption of a semiconductor chip. An area between circuit components, such as wiring patterns, is gradually decreasing, and an etching stop layer is used to stably form the wiring patterns. However, in a process of forming the etching stop layer, a void area is disposed between the wiring pattern and the etching stop layer, thereby reducing reliability of the wiring, and thus, reducing a yield of the semiconductor device.

### SUMMARY

Provided is a semiconductor device in which a void area is prevented from being disposed between an upper wiring capping layer and an etching stop layer to improve reliability of the upper wiring layer.

According to an aspect of the disclosure, a semiconductor device includes a substrate; an interlayer insulating layer disposed on the substrate; an upper wiring trench disposed in the interlayer insulating layer; and an upper wiring layer including: an upper wiring barrier layer disposed along a sidewall and a bottom surface of the upper wiring trench, an upper wiring filling layer disposed on the upper wiring barrier layer so as to fill at least a portion of an inside of the upper wiring trench, and an upper wiring capping layer disposed on an upper surface of the upper wiring filling layer, wherein the upper wiring capping layer includes cobalt (Co), and wherein a volume percentage of a crystal structure having a hexagonal close-packed structure in the upper wiring capping layer is in a range of about 80% to about 100%.

According to an aspect of the disclosure, a semiconductor device includes: a substrate; an interlayer insulating layer disposed on the substrate; a via trench disposed inside the interlayer insulating layer; a via including a via barrier layer disposed along a sidewall and a bottom surface of the via trench, a via filling layer disposed on the via barrier layer so as to fill an inside of the via trench; an upper wiring trench disposed on the via trench in the interlayer insulating layer; and an upper wiring layer including an upper wiring barrier layer disposed along a sidewall and a bottom surface of the upper wiring trench, an upper wiring filling layer disposed on the upper wiring barrier layer so as to fill at least a portion of an inside of the upper wiring trench, and an upper wiring capping layer disposed on an upper surface of the upper wiring filling layer, wherein a first width in a horizontal direction of the via is smaller than a second width in the horizontal direction of the upper wiring layer, and wherein a volume percentage of a crystal structure having a hexagonal close-packed structure contained in the upper wiring capping layer is in a range of about 80% to about 100%.

According to an aspect of the disclosure, a semiconductor device includes: a substrate; an interlayer insulating layer disposed on the substrate; an upper wiring trench disposed in the interlayer insulating layer; an upper wiring layer including an upper wiring barrier layer disposed along a sidewall and a bottom surface of the upper wiring trench, an upper wiring filling layer disposed on the upper wiring barrier layer so as to fill at least a portion of an inside of the upper wiring trench, an upper wiring capping layer disposed on an upper surface of the upper wiring filling layer; and a first etching stop layer disposed on an upper surface of at least one of the interlayer insulating layer, the upper wiring barrier layer and the upper wiring capping layer, wherein a first vertical level of the upper surface of the upper wiring capping layer is higher than a second vertical level of the upper surface of the interlayer insulating layer, wherein a volume percentage of a crystal structure having a hexagonal close-packed structure contained in the upper wiring capping layer is in a range of about 80% to about 100%.

Embodiments of the disclosure are not limited to the above-mentioned embodiments. Other embodiments that are not mentioned in the disclosure may be understood based on following descriptions. Further, it will be easily understood that the embodiments and advantages of the disclosure may be realized by the following detailed descriptions and corresponding drawings.

### BRIEF DESCRIPTION OF THE DRAWINGS

The above and other aspects and features of the disclosure will become more apparent by describing in detail illustrative embodiments thereof with reference to the attached drawings, in which:

FIG. 1 illustrates a semiconductor device according to some embodiments of the disclosure;

FIG. 2 illustrates an enlarged view of a R1 region in FIG. 1;

FIGS. 3 to 9 illustrate intermediate structures corresponding to intermediate operations of a method for manufacturing a semiconductor device according to some embodiments of the disclosure;

FIG. 10 illustrates a semiconductor device according to some other embodiments of the disclosure of the disclosure;

FIG. 11 illustrates an enlarged view of a R2 region in FIG. 10.

FIG. 12 illustrates a semiconductor device according to some other embodiments of the disclosure;

FIG. 13 illustrates an enlarged view of a R3 region in FIG. 12;

FIG. 14 illustrates a semiconductor device according to some other embodiments of the disclosure;

FIG. 15 illustrates an enlarged view of a R4 region in FIG. 14;

FIG. 16 illustrates a semiconductor device according to some other embodiments of the disclosure;

FIGS. 17 to 21 illustrates intermediate structures corresponding to intermediate operations of a method for manufacturing a semiconductor device according to some other embodiments of the disclosure;

FIG. 22 illustrates a semiconductor device according to some other embodiments of the disclosure;

FIG. 23 illustrates a semiconductor device according to some other embodiments of the disclosure of the disclosure; and

FIG. 24 illustrates a semiconductor device according to some other embodiments of the disclosure of the disclosure.

### DETAILED DESCRIPTIONS

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

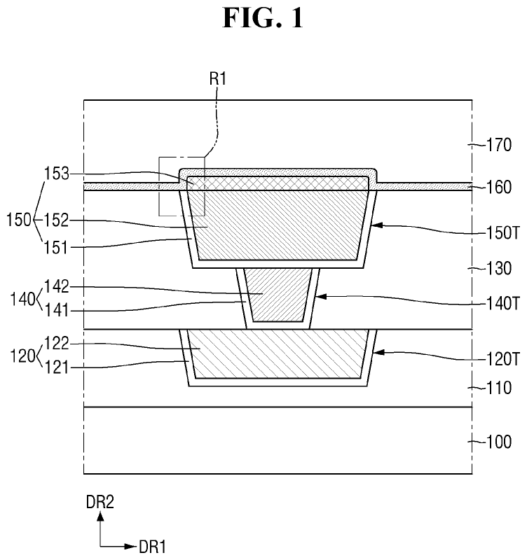

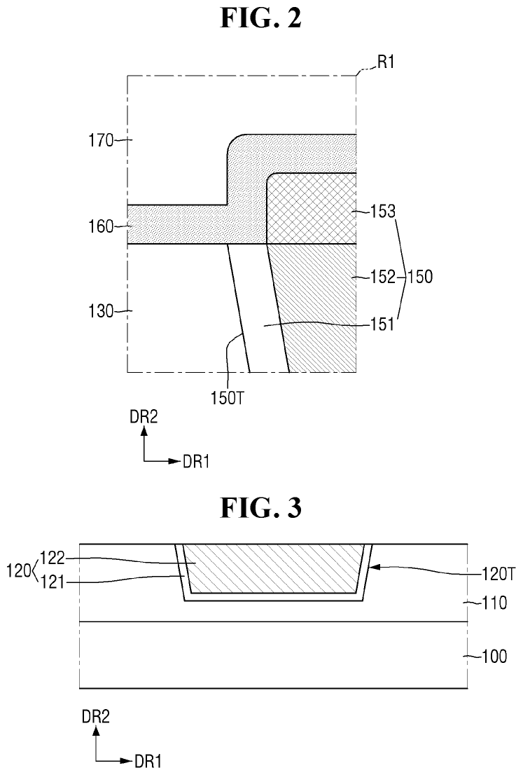

Hereinafter, a semiconductor device according to some embodiments of the disclosure is described with reference to FIG. 1 and FIG. 2.

FIG. 1 illustrates a semiconductor device according to some embodiments of the disclosure. FIG. 2 is an enlarged view of a R1 region in FIG. 1.

Referring to FIG. 1 and FIG. 2, the semiconductor device according to some embodiments of the disclosure includes a substrate 100, a lower interlayer insulating layer 110, a lower wiring layer 120, an interlayer insulating layer 130, a via 140, an upper wiring layer 150, a first etching stop layer 160, and an upper interlayer insulating layer 170.

The substrate 100 may have a structure in which a base substrate and an epi layer are stacked. However, embodiments of the disclosure are not limited thereto. The substrate 100 may be a silicon substrate, a gallium arsenide substrate, a silicon germanium substrate, a ceramic substrate, a quartz substrate, or a glass substrate for a display, etc. or may be a SOI (semiconductor on insulator) substrate.

Furthermore, the substrate 100 may include a conductive pattern. The conductive pattern may be a metal wiring or a contact, etc. or may be a gate electrode of a transistor, a source/drain of a transistor, or a diode. However, embodiments of the disclosure are not limited thereto.

Hereinafter, a horizontal direction DR1 may be defined as a direction parallel to an upper surface of the substrate 100. The vertical direction DR2 may be defined as a direction perpendicular to the horizontal direction DR1. That is, the vertical direction DR2 may be defined as a direction perpendicular to the upper surface of the substrate 100.

The lower interlayer insulating layer 110 may be disposed on the upper surface of the substrate 100. For example, the lower interlayer insulating layer 110 may include at least one of silicon oxide, silicon nitride, silicon oxynitride, and a low dielectric constant material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, embodiments of the disclosure are not limited thereto.

The lower wiring trench 120T (dashed line in FIG. 1) may be formed (disposed) in the lower interlayer insulating layer 110. The lower wiring trench 120T may be formed to be recessed from an upper surface of the lower interlayer insulating layer 110 into an inside of the lower interlayer insulating layer 110. For example, a sidewall and a bottom surface of the lower wiring trench 120T may be defined by the lower interlayer insulating layer 110. For example, a width in the horizontal direction DR1 of the lower wiring trench 120T may gradually decrease as the lower wiring trench 120T extends toward the upper surface of the substrate 100.

The lower wiring layer 120 may be disposed in the lower wiring trench 120T. That is, the lower wiring layer 120 may be disposed in the lower interlayer insulating layer 110. For example, a width in the horizontal direction DR1 of the lower wiring layer 120 may gradually decrease as the lower wiring layer 120 extends toward the upper surface of the substrate 100. For example, an upper surface of the lower wiring layer 120 may not be covered with an upper surface of the lower interlayer insulating layer 110 so as to be exposed. The lower wiring layer 120 may include a lower wiring barrier layer 121 and a lower wiring filling layer 122.

The lower wiring barrier layer 121 may be disposed along the sidewall and the bottom surface of the lower wiring trench 120T. For example, the lower wiring barrier layer 121 may be formed conformally. For example, a top surface of the lower wiring barrier layer 121 may not be covered with the upper surface of the lower interlayer insulating layer 110 so as to be exposed. The lower wiring barrier layer 121 may include, for example, one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and combinations thereof. However, embodiments of the disclosure are not limited thereto.

The lower wiring filling layer 122 may be disposed on the lower wiring barrier layer 121 and inside the lower wiring trench 120T. The lower wiring filling layer 122 may fill an inside of the lower wiring trench 120T while being disposed on the lower wiring barrier layer 121. For example, an upper surface of the lower wiring filling layer 122 may not be covered with an upper surface of the lower interlayer insulating layer 110 so as to be exposed. The lower wiring filling layer 122 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), or rhodium (Rh). However, embodiments of the disclosure are not limited thereto.

The interlayer insulating layer 130 may be disposed on each of the upper surface of the lower interlayer insulating layer 110 and the upper surface of the lower wiring layer 120. For example, the interlayer insulating layer 130 may include at least one of silicon oxide, silicon nitride, silicon oxynitride, and a low dielectric constant material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, embodiments of the disclosure are not limited thereto.

A via trench 140T (dashed line in FIG. 1) may be formed in the interlayer insulating layer 130. For example, a bottom surface of the via trench 140T may be defined by the lower wiring layer 120. Furthermore, a sidewall of the via trench 140T may be defined by the interlayer insulating layer 130. For example, a width in the horizontal direction DR1 of the via trench 140T may gradually decrease as the via trench 140T extends toward the upper surface of the lower wiring layer 120.

The via 140 may be disposed in the via trench 140T. That is, the via 140 may be disposed in the interlayer insulating layer 130. For example, a width in the horizontal direction DR1 of the via 140 may gradually decrease as the via 140 extends toward the upper surface of the lower wiring layer 120. The via 140 may be connected to the lower wiring layer 120. The via 140 may include a via barrier layer 141 and a via filling layer 142.

The via barrier layer 141 may be disposed along the sidewall and the bottom surface of the via trench 140T. For example, the via barrier layer 141 may be formed conformally. The via barrier layer 141 may include, for example, one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and combinations thereof. However, embodiments of the disclosure are not limited thereto.

The via filling layer 142 may be disposed on the via barrier layer 141 and inside the via trench 140T. The via filling layer 142 may fill an inside of the via trench 140T while being disposed on the via barrier layer 141. The via filling layer 142 may include, for example, at least one of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), or rhodium (Rh). However, embodiments of the disclosure are not limited thereto.

An upper wiring trench 150T (dashed line in FIG. 1) may be formed in the interlayer insulating layer 130. The upper wiring trench 150T may be formed on the via trench 140T while the upper wiring trench 150T is disposed in the interlayer insulating layer 130. The upper wiring trench 150T may be formed to be recessed from the upper surface of the interlayer insulating layer 130 into the inside of the interlayer insulating layer 130. For example, a bottom surface of the upper wiring trench 150T may be defined by an upper surface of the via 140 and the interlayer insulating layer 130. A sidewall of the upper wiring trench 150T may be defined by the interlayer insulating layer 130. For example, a width in the horizontal direction DR1 of the bottom surface of the upper wiring trench 150T may be larger than a width in the horizontal direction DR1 of the upper surface of the via trench 140T.

The upper wiring layer 150 may be disposed in the upper wiring trench 150T. That is, the upper wiring layer 150 may be disposed in the interlayer insulating layer 130. For example, a width in the horizontal direction DR1 of the upper wiring layer 150 may gradually decrease as the upper wiring layer 150 extends toward the upper surface of the via 140. For example, a vertical level of an upper surface of the upper wiring layer 150 may be higher than a vertical level of the upper surface of the interlayer insulating layer 130. That is, at least a portion of the upper wiring layer 150 may protrude in the vertical direction DR2 beyond the upper surface of the interlayer insulating layer 130. For example, a width in the horizontal direction DR1 of the upper surface of the via 140 may be smaller than a width in the horizontal direction DR1 of the lower surface of the upper wiring layer 150. The upper wiring layer 150 may be connected to the via 140. The upper wiring layer 150 may include an upper wiring barrier layer 151, an upper wiring filling layer 152, and an upper wiring capping layer 153.

The upper wiring barrier layer 151 may be disposed along the sidewall and the bottom surface of the upper wiring trench 150T. For example, the upper wiring barrier layer 151 may be formed conformally. For example, a top surface of the upper wiring barrier layer 151 may not be covered with the upper surface of the interlayer insulating layer 130 so as to be exposed. For example, the upper wiring barrier layer 151 may include, for example, one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), and combinations thereof. However, embodiments of the disclosure are not limited thereto.

The upper wiring filling layer 152 may be disposed on the upper wiring barrier layer 151 and inside the upper wiring trench 150T. The upper wiring filling layer 152 may fill at least a portion of the inside of the upper wiring trench 150T while being disposed on the upper wiring barrier layer 151. FIG. 1 shows that the upper surface of the upper wiring filling layer 152 is coplanar with the upper surface of the interlayer insulating layer 130. However, embodiments of the disclosure are not limited thereto. In some other embodiments, a vertical level of the upper surface of the upper wiring filling layer 152 may be higher than a vertical level of the upper surface of the interlayer insulating layer 130. In some other embodiments, the vertical level of the upper surface of the upper wiring filling layer 152 may be lower than the vertical level of the upper surface of the interlayer insulating layer 130.

For example, the upper wiring filling layer 152 may be spaced apart from the via filling layer 142 in the vertical direction DR2. For example, the upper wiring barrier layer 151 may be disposed between the upper surface of the via filling layer 142 and the lower surface of the upper wiring filling layer 152. For example, the upper wiring filling layer 152 may include copper (Cu). In some other embodiments, the upper wiring filling layer 152 may include at least one of carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), or rhodium (Rh). However, embodiments of the disclosure are not limited thereto.

The upper wiring capping layer 153 may be disposed on the upper surface of the upper wiring filling layer 152. The upper wiring capping layer 153 may be in contact with the upper surface of the upper wiring filling layer 152. For example, a vertical level of the upper surface of the upper wiring capping layer 153 may be higher than a vertical level of the upper surface of the interlayer insulating layer 130. That is, the upper wiring capping layer 153 may protrude in the vertical direction (DR2) beyond the upper surface of the interlayer insulating layer 130.

For example, a material of the upper wiring capping layer 153 may be different from a material of the upper wiring filling layer 152. For example, the upper wiring capping layer 153 may include cobalt (Co). For example, the upper wiring capping layer 153 may contain a crystal structure having a hexagonal close-packed structure. For example, a volume percentage of the crystal structure having the hexagonal close-packed structure contained in the upper wiring capping layer 153 may range from 80% to 100%. That is, the volume of the crystal structure having the hexagonal close-packed structure relative to an entire volume of the upper wiring capping layer 153 may range from 80% to 100%.

For example, the upper wiring capping layer 153 may contain a crystal structure having a face-centered cubic structure. For example, a volume percentage of the crystal structure having the face-centered cubic structure contained in the upper wiring capping layer 153 may be smaller than 20%. That is, the volume of the crystal structure having the face-centered cubic structure relative to the entire volume of the upper wiring capping layer 153 may be smaller than 20%.

The first etching stop layer 160 may be disposed on each of the upper surface of the interlayer insulating layer 130 and the upper surface of the upper wiring layer 150. For example, the first etching stop layer 160 may contact each of the upper surface of the interlayer insulating layer 130 and the upper surface of the upper wiring layer 150. For example, the first etching stop layer 160 may be in contact with each of the top surface of the upper wiring barrier layer 151 and a sidewall and an upper surface of the upper wiring capping layer 153. For example, the first etching stop layer 160 may be formed conformally.

The first etching stop layer 160 may include, for example, at least one of aluminum nitride (AlN), aluminum oxide (AlO), hafnium oxide (HfO), zirconium oxide (ZrO), hafnium nitride (HfN), zirconium nitride (ZrN), silicon. oxide (SiO₂), silicon nitride (SiN), silicon oxynitride (SiCN), silicon oxycarbide (SiOC), silicon carbide (SiC), or a low dielectric constant material.

The upper interlayer insulating layer 170 may be disposed on the upper surface of the first etching stop layer 160. The upper interlayer insulating layer 170 may be in contact with the upper surface of the first etching stop layer 160. For example, the upper interlayer insulating layer 170 may include at least one of silicon oxide, silicon nitride, silicon oxynitride, and a low dielectric constant material. The low dielectric constant material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, embodiments of the disclosure are not limited thereto.

Hereinafter, with reference to FIG. 1, FIG. 3 to FIG. 9, a method for manufacturing a semiconductor device according to some embodiments of the disclosure is described.

FIGS. 3 to 9 illustrate intermediate structures corresponding to intermediate operations of a method for manufacturing a semiconductor device according to some embodiments of the disclosure.

Referring to FIG. 3, the lower interlayer insulating layer 110 may be formed on the upper surface of the substrate 100. Subsequently, the lower wiring trench 120T may be formed in the lower interlayer insulating layer 110. The lower wiring trench 120T may be formed to be recessed from the upper surface of the lower interlayer insulating layer 110 into the inside of the lower interlayer insulating layer 110.

Subsequently, the lower wiring layer 120 including the lower wiring barrier layer 121 and the lower wiring filling layer 122 may be formed in the lower wiring trench 120T. The lower wiring barrier layer 121 may be formed along the sidewall and the bottom surface of the lower wiring trench 120T. For example, the lower wiring barrier layer 121 may be formed conformally. The lower wiring filling layer 122 may fill the inside of the lower wiring trench 120T while being disposed on the lower wiring barrier layer 121.

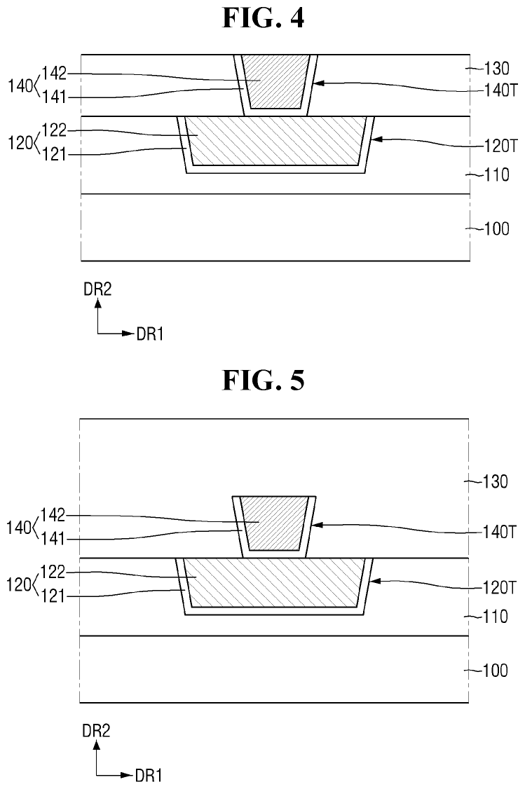

Referring to FIG. 4, the interlayer insulating layer 130 may be formed on each of the upper surface of the lower interlayer insulating layer 110 and the upper surface of the lower wiring layer 120. Subsequently, the via trench 140T may be formed in the interlayer insulating layer 130. The via trench 140T may be formed to be recessed from the upper surface of the interlayer insulating layer 130 into the inside of the interlayer insulating layer 130. For example, the via trench 140T may expose the upper surface of the lower wiring layer 120.

Subsequently, the via 140 including the via barrier layer 141 and the via filling layer 142 may be formed in the via trench 140T. The via barrier layer 141 may be formed along the sidewall and the bottom surface of the via trench 140T. For example, the via barrier layer 141 may be formed conformally. The via filling layer 142 may fill the inside of the via trench 140T while being disposed on the via barrier layer 141.

Referring to FIG. 5, the interlayer insulating layer 130 may be additionally formed on each of the upper surface of the interlayer insulating layer 130 and the upper surface of the via 140. The additionally formed interlayer insulating layer 130 may cover the upper surface of the via 140.

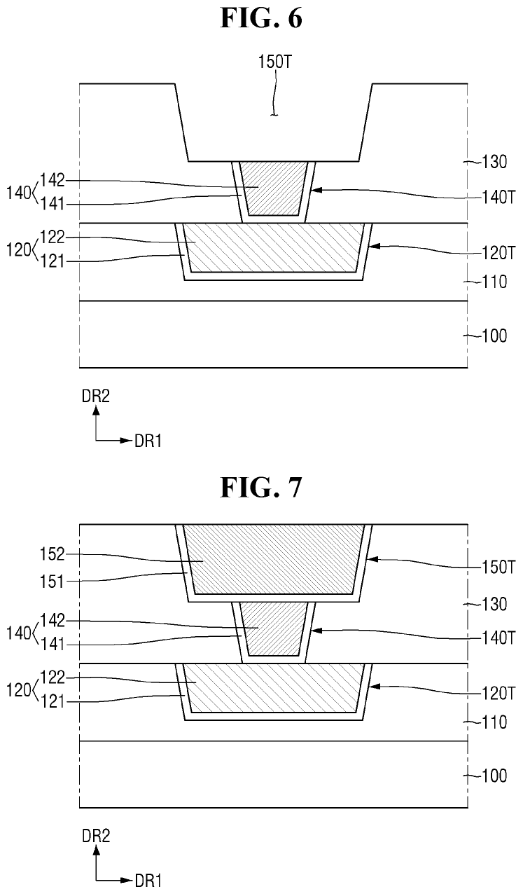

Referring to FIG. 6, the upper wiring trench 150T may be formed on the upper surface of the via 140 and inside the interlayer insulating layer 130. The upper wiring trench 150T may be formed to be recessed from the upper surface of the interlayer insulating layer 130 into the inside of the interlayer insulating layer 130. For example, the upper wiring trench 150T may expose the upper surface of the via 140.

Referring to FIG. 7, the upper wiring barrier layer 151 and the upper wiring filling layer 152 may be formed in the upper wiring trench 150T. The upper wiring barrier layer 151 may be formed along the sidewall and the bottom surface of the upper wiring trench 150T. For example, the upper wiring barrier layer 151 may be formed conformally. The upper wiring filling layer 152 may fill the inside of the upper wiring trench 150T while being disposed on the upper wiring barrier layer 151.

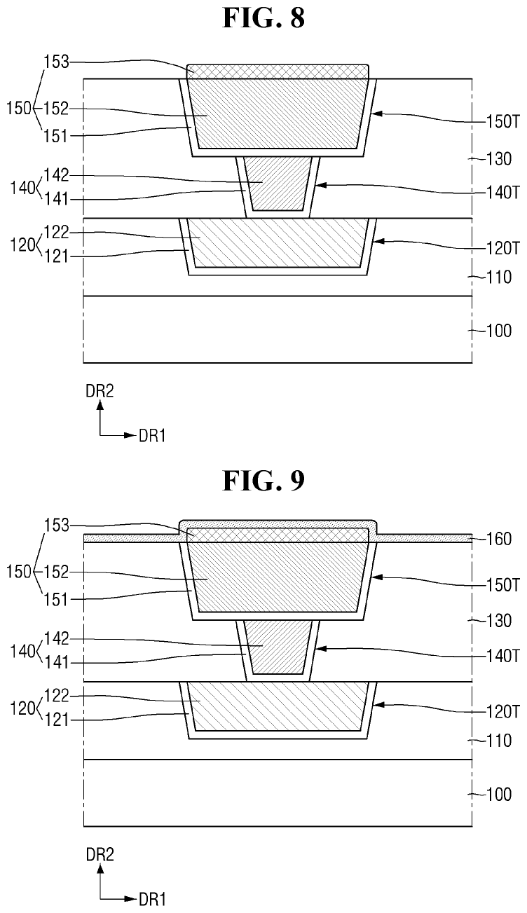

Referring to FIG. 8, an upper wiring capping layer 153 may be formed on the upper surface of the upper wiring filling layer 152. For example, the upper wiring filling layer 152 may be formed so as to protrude in the vertical direction DR2 beyond the upper surface of the interlayer insulating layer 130. As a result, the upper wiring layer 150 including the upper wiring barrier layer 151, the upper wiring filling layer 152, and the upper wiring capping layer 153 may be formed. For example, the upper wiring capping layer 153 may contain the crystal structure having the hexagonal close-packed structure. For example, the volume percentage of the crystal structure having the hexagonal close-packed structure contained in the upper wiring capping layer 153 may range from 80% to 100%.

Referring to FIG. 9, the first etching stop layer 160 may be formed on each of the upper surface of the interlayer insulating layer 130 and the upper surface of the upper wiring layer 150. For example, the first etching stop layer 160 may be in contact with each of the upper surface of the interlayer insulating layer 130, the top surface of the upper wiring barrier layer 151, and the sidewall and the upper surface of the upper wiring capping layer 153. For example, in a process in which the first etching stop layer 160 is formed, the first etching stop layer 160 may be formed using a process gas that does not contain nitrogen atoms (for example, a process gas that does not contain NH₃ and N₂). Thus, after the first etching stop layer 160 has been formed, the volume percentage of the crystal structure having the hexagonal close-packed structure contained in the upper wiring capping layer 153 may be maintained at 80% or greater.

Referring to FIG. 1, the upper interlayer insulating layer 170 may be formed on the upper surface of the first etching stop layer 160. In this manufacturing process, the semiconductor device as shown in FIG. 1 may be manufactured.

In the method for manufacturing the semiconductor device according to some embodiments of the disclosure, the first etching stop layer 160 may be formed on the upper wiring capping layer 153 using the process gas not containing nitrogen atoms (e.g., a process gas not containing NH₃ and N₂). Thus, after the first etching stop layer 160 has been formed, the volume percentage of the crystal structure having the hexagonal close-packed structure contained in the upper wiring capping layer 153 may be maintained at 80% or greater.

In the semiconductor device according to some embodiments of the disclosure manufactured by the above manufacturing method, the volume percentage of the crystal structure having the hexagonal close-packed structure contained in the upper wiring capping layer 153 may be in a range of 80% to 100%, such that adhesion between the upper wiring capping layer 153 and the first etching stop layer 160 may be improved. For this reason, in the semiconductor device according to some embodiments of the disclosure, the void may be prevented from being generated between the surface of the upper wiring capping layer 153 and the first etching stop layer 160, thereby improving reliability of the upper wiring layer 150.

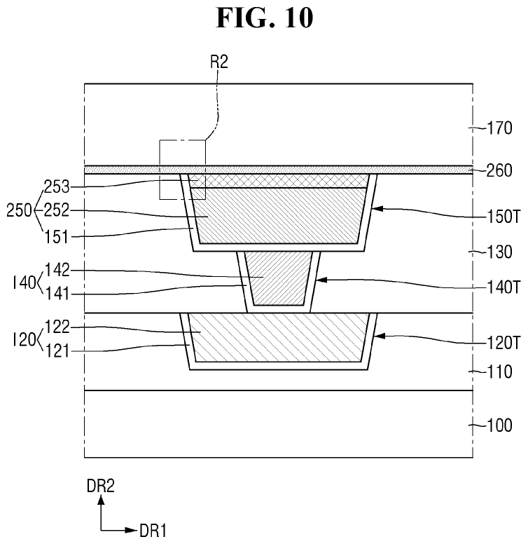

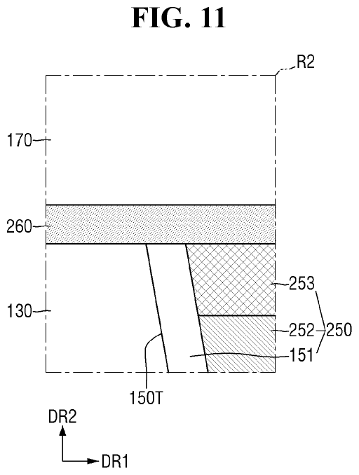

Hereinafter, a semiconductor device according to some other embodiments of the disclosure is described with referring to FIG. 10 and FIG. 11. Differences thereof from the semiconductor device as shown in FIG. 1 and FIG. 2 will be mainly described.

FIG. 10 illustrates a semiconductor device according to some other embodiments of the disclosure. FIG. 11 is an enlarged view of a R2 region in FIG. 10.

Referring to FIG. 10 and FIG. 11, in the semiconductor device according to some other embodiments of the disclosure, an upper wiring capping layer 253 may be disposed inside the upper wiring trench 150T.

For example, the upper wiring layer 250 may include the upper wiring barrier layer 151, an upper wiring filling layer 252, and an upper wiring capping layer 253. Inside the upper wiring trench 150T, a sidewall of the upper wiring capping layer 253 may be in contact with the upper wiring barrier layer 151. FIG. 1 shows that an upper surface of the upper wiring capping layer 253 is coplanar with the upper surface of the interlayer insulating layer 130, but embodiments of the disclosure are not limited thereto. In some other embodiments, a vertical level of the upper surface of the upper wiring capping layer 253 may be higher than a vertical level of the upper surface of the interlayer insulating layer 130. Furthermore, in some other embodiments, a vertical level of the upper surface of the upper wiring capping layer 253 may be lower than a vertical level of the upper surface of the interlayer insulating layer 130. The first etching stop layer 260 may be disposed on the upper surface of each of the upper wiring barrier layer 151, the upper wiring filling layer 252, and the upper wiring capping layer 253.

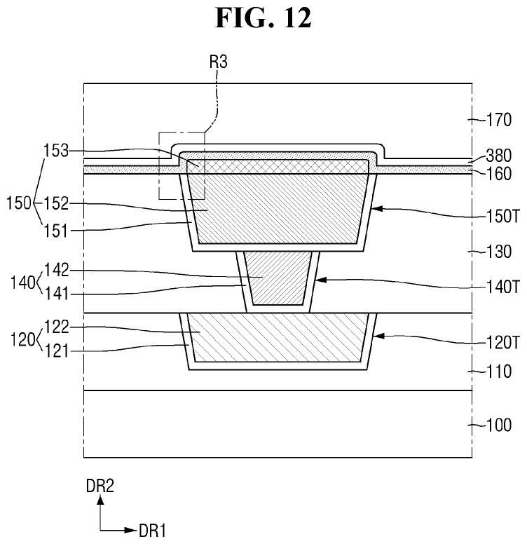

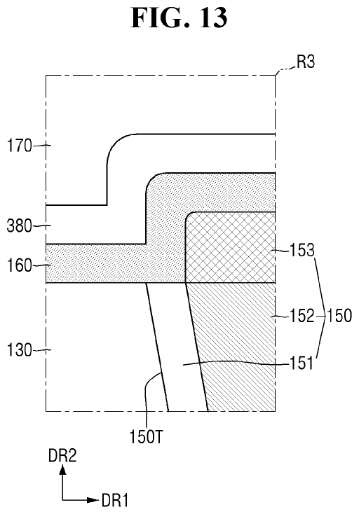

Hereinafter, with reference to FIG. 12 and FIG. 13, a semiconductor device according to some other embodiments of the disclosure is described. Differences thereof from the semiconductor device as shown in FIG. 1 and FIG. 2 will be mainly described.

FIG. 12 illustrates a semiconductor device according to some other embodiments of the disclosure. FIG. 13 is an enlarged view of a R3 region in FIG. 12.

Referring to FIG. 12 and FIG. 13, in the semiconductor device according to some other embodiments of the disclosure, the etching stop layer including the first etching stop layer 160 formed as a stack of double films.

For example, a second etching stop layer 380 may be disposed on the upper surface of the first etching stop layer 160. The second etching stop layer 380 may be in contact with the upper surface of the first etching stop layer 160. For example, a material in the second etching stop layer 380 may be different from a material in the first etching stop layer 160. For example, the first etching stop layer 160 may include one of aluminum nitride (AlN), aluminum oxide (AlO), and silicon nitride (SiN). For example, the second etching stop layer 380 may include one of silicon oxide (SiO₂), silicon oxynitride (SiCN), silicon oxycarbide (SiOC), and silicon carbide (SiC). The upper interlayer insulating layer 170 may be in contact with an upper surface of the second etching stop layer 380 while being disposed on the upper surface of the second etching stop layer 380.

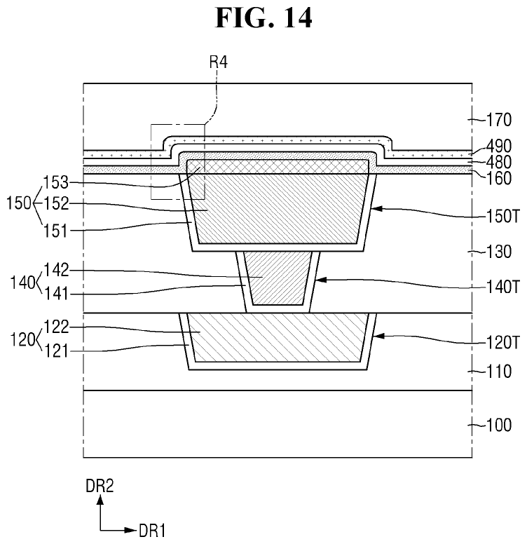

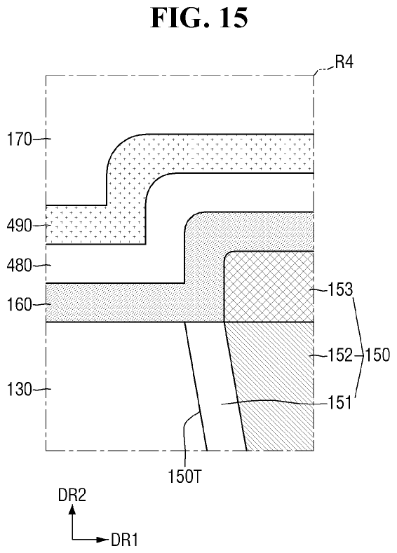

Hereinafter, with reference to FIG. 14 and FIG. 15, a semiconductor device according to some still yet other embodiments of the disclosure is described. Differences thereof from the semiconductor device as shown in FIG. 1 and FIG. 2 will be mainly described.

FIG. 14 illustrates a semiconductor device according to some still yet other embodiments of the disclosure. FIG. 15 is an enlarged view of a R4 region in FIG. 14.

Referring to FIG. 14 and FIG. 15, in the semiconductor device according to some still yet other embodiments of the disclosure, the etching stop layer including the first etching stop layer 160 may be formed as a stack of triple films.

For example, a second etching stop layer 480 and a third etching stop layer 490 may be sequentially disposed on the upper surface of the first etching stop layer 160. That is, the second etching stop layer 480 in contact with the upper surface of the first etching stop layer 160 may be disposed on the upper surface of the first etching stop layer 160. Furthermore, the third etching stop layer 490 in contact with an upper surface of the second etching stop layer 480 may be disposed on the upper surface of the second etching stop layer 480.

For example, a material in the second etching stop layer 480 may be different from a material in the first etching stop layer 160. Furthermore, a material in the third etching stop layer 490 may be different from a material in the second etching stop layer 480. For example, the first etching stop layer 160 may include either aluminum nitride (AlN) or aluminum oxide (AlO). For example, the second etching stop layer 480 may include one of silicon oxide (SiO2), silicon nitride (SiN), silicon oxynitride (SiCN), silicon oxycarbide (SiOC), and silicon carbide (SiC). For example, the third etching stop layer 490 may include either aluminum nitride (AlN) or aluminum oxide (AlO). The upper interlayer insulating layer 170 may be in contact with an upper surface of the third etching stop layer 490 while being disposed on the upper surface of the third etching stop layer 490.

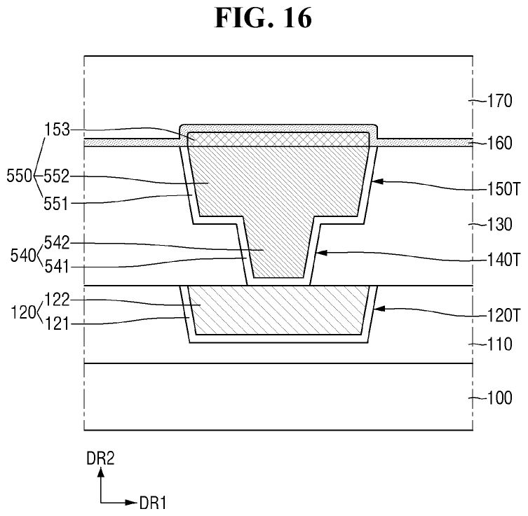

Hereinafter, with reference to FIG. 16, a semiconductor device according to some still yet other embodiments of the disclosure is described. Differences thereof from the semiconductor device as shown in FIG. 1 and FIG. 2 will be mainly described.

FIG. 16 illustrates a semiconductor device according to some still yet other embodiments of the disclosure.

Referring to FIG. 16, in the semiconductor device according to some still yet other embodiments of the disclosure, an upper wiring layer 550 and a via 540 may be formed in a dual damascene process.

For example, the via 540 may include a via barrier layer 541 and a via filling layer 542. The via barrier layer 541 may be disposed along the sidewall and the bottom surface of the via trench 140T. The via filling layer 542 may fill the inside of the via trench 140T while being disposed on the via barrier layer 541.

For example, the upper wiring layer 550 may include an upper wiring barrier layer 551, an upper wiring filling layer 552, and the upper wiring capping layer 153. The upper wiring barrier layer 551 may be disposed along the sidewall and a portion of the bottom surface of the upper wiring trench 150T. For example, the upper wiring barrier layer 551 and the via barrier layer 541 may be formed integrally with each other and be monolithic. The upper wiring filling layer 552 may fill the inside of the upper wiring trench 150T while being disposed on the upper wiring barrier layer 551. An upper surface of the via filling layer 542 may be in contact with a lower surface of the upper wiring filling layer 552. For example, the upper wiring filling layer 552 and the via filling layer 542 may be formed integrally with each other and be monolithic. The upper wiring capping layer 153 may be in contact with an upper surface of the upper wiring filling layer 552 while being disposed on the upper surface of the upper wiring filling layer 552.

Hereinafter, with reference to FIGS. 16 to 21, a method for manufacturing a semiconductor device according to some other embodiments of the disclosure is described.

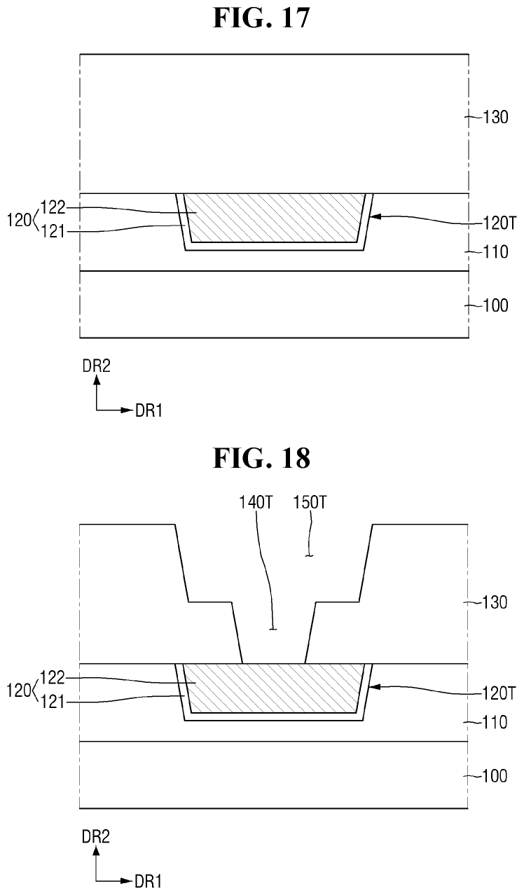

FIGS. 17 to 21 are diagrams of intermediate structures corresponding to intermediate operations of a method for manufacturing a semiconductor device according to some other embodiments of the disclosure.

Referring to FIG. 17, the lower interlayer insulating layer 110 may be formed on the upper surface of the substrate 100. Subsequently, the lower wiring trench 120T may be formed inside the lower interlayer insulating layer 110. The lower wiring trench 120T may be formed to be recessed from the upper surface of the lower interlayer insulating layer 110 into the inside of the lower interlayer insulating layer 110.

Subsequently, the lower wiring layer 120 including the lower wiring barrier layer 121 and the lower wiring filling layer 122 may be formed in the lower wiring trench 120T. The lower wiring barrier layer 121 may be formed along the sidewall and the bottom surface of the lower wiring trench 120T. For example, the lower wiring barrier layer 121 may be formed conformally. The lower wiring filling layer 122 may fill the inside of the lower wiring trench 120T while being disposed on the lower wiring barrier layer 121. Subsequently, the interlayer insulating layer 130 may be formed on each of the upper surface of the lower interlayer insulating layer 110 and the upper surface of the lower wiring layer 120.

Referring to FIG. 18, each of the via trench 140T and the upper wiring trench 150T may be formed inside the interlayer insulating layer 130. The upper wiring trench 150T may be formed on top of the via trench 140T. For example, the width in the horizontal direction DR1 of the upper wiring trench 150T may be larger than the width in the horizontal direction DR1 of the via trench 140T. The upper surface of the lower wiring layer 120 may be exposed through the via trench 140T and upper wiring trench 150T.

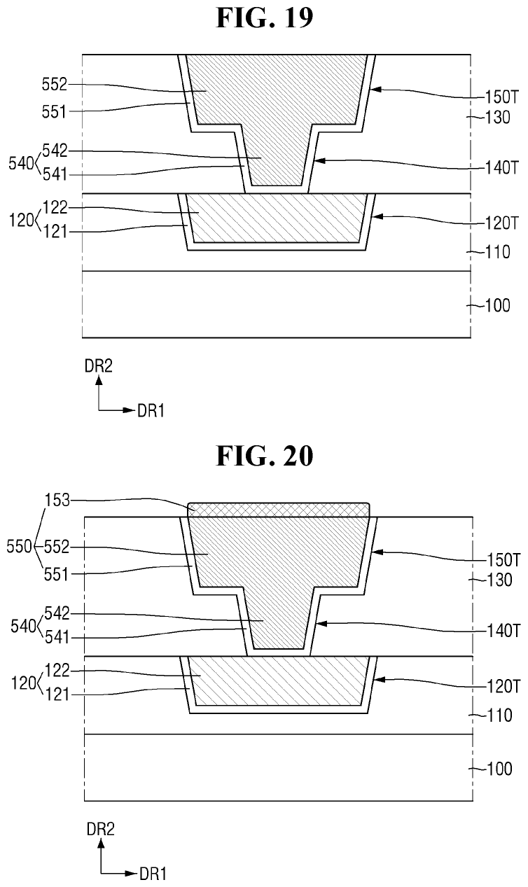

Referring to FIG. 19, the via 540 including the via barrier layer 541 and the via filling layer 542 may be formed in the via trench 140T. For example, the via barrier layer 541 may be formed along the sidewall and the bottom surface of the via trench 140T. The via filling layer 542 may fill the inside of the via trench 140T while being disposed on the via barrier layer 541.

Furthermore, the upper wiring barrier layer 551 and the upper wiring filling layer 552 may be formed in the upper wiring trench 150T. For example, the upper wiring barrier layer 551 may be formed along the sidewall and the portion of the bottom surface of the upper wiring trench 150T. The upper wiring filling layer 552 may fill the inside of the upper wiring trench 150T while being disposed on the upper wiring barrier layer 551. The upper surface of the via filling layer 542 may be in contact with the lower surface of the upper wiring filling layer 552.

The via barrier layer 541 and the upper wiring barrier layer 551 may be formed integrally with each other and be monolithic. For example, the via barrier layer 541 and the upper wiring barrier layer 551 may be formed in the same manufacturing process. The via filling layer 542 and the upper wiring filling layer 552 may be formed integrally with each other and be monolithic. For example, the via filling layer 542 and the upper wiring filling layer 552 may be formed in the same manufacturing process.

Referring to FIG. 20, the upper wiring capping layer 153 may be formed on the upper surface of the upper wiring filling layer 552. For example, the upper wiring filling layer 552 may be formed to protrude in the vertical direction DR2 beyond the upper surface of the interlayer insulating layer 130. As a result, the upper wiring layer 550 including the upper wiring barrier layer 551, the upper wiring filling layer 552, and the upper wiring capping layer 153 may be formed. For example, the upper wiring capping layer 153 may contain the crystal structure having the hexagonal close-packed structure. For example, the volume percentage of the crystal structure having the hexagonal close-packed structure contained in the upper wiring capping layer 153 may range from 80% to 100%.

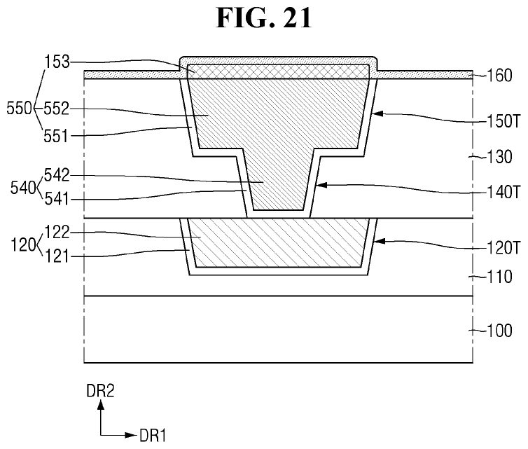

Referring to FIG. 21, the first etching stop layer 160 may be formed on each of the upper surface of the interlayer insulating layer 130 and the upper surface of the upper wiring layer 550. For example, the first etching stop layer 160 may be in contact with each of the upper surface of the interlayer insulating layer 130, the top surface of the upper wiring barrier layer 551, and the sidewall and the upper surface of the upper wiring capping layer 153. For example, in the process in which the first etching stop layer 160 is formed, the first etching stop layer 160 may be formed using a process gas that does not contain nitrogen atoms (for example, a process gas that does not contain NH₃ and N₂). Thus, after the first etching stop layer 160 has been formed, the volume percentage of the crystal structure having the hexagonal close-packed structure contained in the upper wiring capping layer 153 may be maintained at 80% or greater.

Referring to FIG. 16, the upper interlayer insulating layer 170 may be formed on the upper surface of the first etching stop layer 160. In this manufacturing process, the semiconductor device as shown in FIG. 16 may be manufactured.

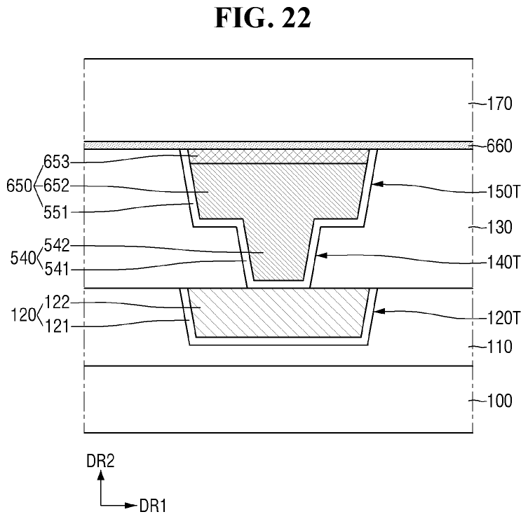

Hereinafter, with reference to FIG. 22, a semiconductor device according to some other embodiments of the disclosure is described. Differences thereof from the semiconductor device as shown in FIG. 16 will be mainly described.

FIG. 22 illustrates a semiconductor device according to some other embodiments of the disclosure.

Referring to FIG. 22, in the semiconductor device according to some other embodiments of the disclosure, an upper wiring layer 650 and via the 540 may be formed in a dual damascene process. Furthermore, an upper wiring capping layer 653 may be disposed inside the upper wiring trench 150T.

For example, the upper wiring layer 650 may include the upper wiring barrier layer 551, an upper wiring filling layer 652, and the upper wiring capping layer 653. For example, the upper wiring barrier layer 551 and the via barrier layer 541 may be formed integrally with each other and be monolithic. The upper surface of the via filling layer 542 may be in contact with a lower surface of the upper wiring filling layer 652. For example, the upper wiring filling layer 552 and the via filling layer 542 may be formed integrally with each other and be monolithic. The upper wiring capping layer 653 may contact an upper surface of the upper wiring filling layer 652 while being disposed on the upper surface of the upper wiring filling layer 652. For example, inside the upper wiring trench 150T, a sidewall of the upper wiring capping layer 653 may contact the upper wiring barrier layer 551.

FIG. 22 shows that an upper surface of the upper wiring capping layer 653 is coplanar with the upper surface of the interlayer insulating layer 130. However, embodiments of the disclosure are not limited thereto. In some other embodiments, a vertical level of the upper surface of the upper wiring capping layer 653 may be higher than a vertical level of the upper surface of the interlayer insulating layer 130. Furthermore, in some other embodiments, the vertical level of the upper surface of the upper wiring capping layer 653 may be lower than the vertical level of the upper surface of the interlayer insulating layer 130. The first etching stop layer 660 may be disposed on the upper surface of each of the upper wiring barrier layer 551, the upper wiring filling layer 652, and the upper wiring capping layer 653.

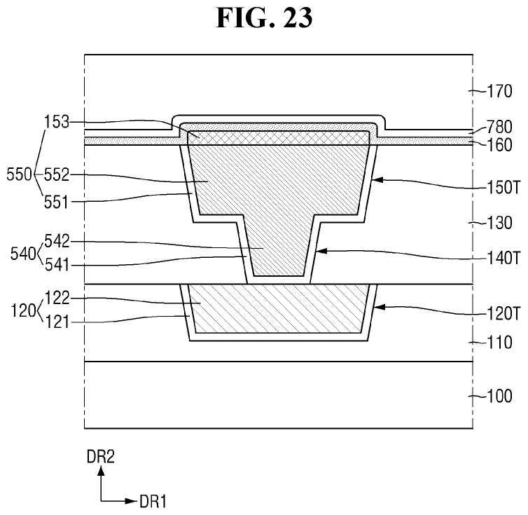

Hereinafter, with reference to FIG. 23, a semiconductor device according to some other embodiments of the disclosure is described. Differences thereof from the semiconductor device as shown in FIG. 16 will be mainly described.

FIG. 23 illustrates a semiconductor device according to some other embodiments of the disclosure.

Referring to FIG. 23, in the semiconductor device according to some other embodiments of the disclosure, the upper wiring layer 550 and the via 540 may be formed in a dual damascene process. Furthermore, the etching stop layer including the first etching stop layer 160 may be formed as a stack of double films.

For example, the upper wiring layer 550 may include the upper wiring barrier layer 551, the upper wiring filling layer 552, and the upper wiring capping layer 153. For example, the upper wiring barrier layer 551 and the via barrier layer 541 may be formed integrally with each other and be monolithic. The upper surface of the via filling layer 542 may be in contact with the lower surface of the upper wiring filling layer 552. For example, the upper wiring filling layer 552 and the via filling layer 542 may be formed integrally with each other and be monolithic. The upper wiring capping layer 153 may be in contact with the upper surface of the upper wiring filling layer 552 while being disposed on the upper surface of the upper wiring filling layer 552.

For example, a second etching stop layer 780 may be disposed on the upper surface of the first etching stop layer 160. The second etching stop layer 780 may be in contact with the upper surface of the first etching stop layer 160. For example, a material in the second etching stop layer 780 may be different from a material in the first etching stop layer 160. For example, the first etching stop layer 160 may include one of aluminum nitride (AlN), aluminum oxide (AlO), and silicon nitride (SiN). For example, the second etching stop layer 780 may include one of silicon oxide (SiO2), silicon oxynitride (SiCN), silicon oxycarbide (SiOC), and silicon carbide (SiC). The upper interlayer insulating layer 170 may be in contact with an upper surface of the second etching stop layer 780 while being disposed on the upper surface of the second etching stop layer 780.

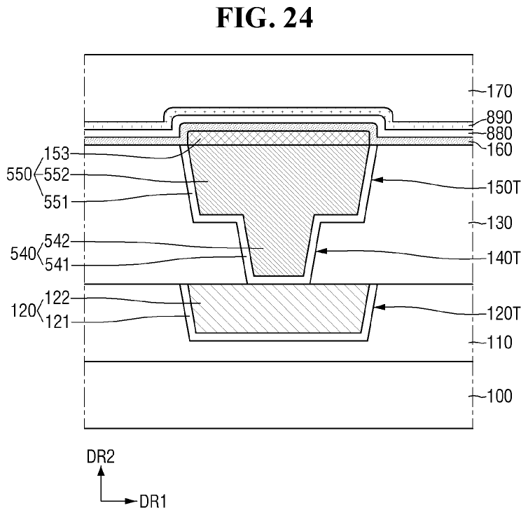

Hereinafter, with reference to FIG. 24, a semiconductor device according to some other embodiments of the disclosure is described. Differences thereof from the semiconductor device as shown in FIG. 16 will be mainly described.

FIG. 24 illustrates a semiconductor device according to some other embodiments of the disclosure.

Referring to FIG. 24, in the semiconductor device according to some other embodiments of the disclosure, the upper wiring layer 550 and the via 540 may be formed in a dual damascene process. Furthermore, the etching stop layer including the first etching stop layer 160 may be formed as a stack of triple films.

For example, the upper wiring layer 550 may include the upper wiring barrier layer 551, the upper wiring filling layer 552, and the upper wiring capping layer 153. For example, the upper wiring barrier layer 551 and the via barrier layer 541 may be formed integrally with each other and be monolithic. The upper surface of the via filling layer 542 may be in contact with the lower surface of the upper wiring filling layer 552. For example, the upper wiring filling layer 552 and the via filling layer 542 may be formed integrally with each other and be monolithic. The upper wiring capping layer 153 may be in contact with the upper surface of the upper wiring filling layer 552 while being disposed on the upper surface of the upper wiring filling layer 552.

For example, a second etching stop layer 880 and a third etching stop layer 890 may be sequentially disposed on the upper surface of the first etching stop layer 160. That is, the second etching stop layer 880 in contact with the upper surface of the first etching stop layer 160 may be disposed on the upper surface of the first etching stop layer 160. Furthermore, the third etching stop layer 890 in contact with an upper surface of the second etching stop layer 880 may be disposed on the upper surface of the second etching stop layer 880.

For example, a material in the second etching stop layer 880 may be different from a material in the first etching stop layer 160. Furthermore, a material in the third etching stop layer 890 may be different from a material in the second etching stop layer 880. For example, the first etching stop layer 160 may include either aluminum nitride (AlN) or aluminum oxide (AlO). For example, the second etching stop layer (880) may include one of silicon oxide (SiO2), silicon nitride (SiN), silicon oxynitride (SiCN), silicon oxycarbide (SiOC), and silicon carbide (SiC). For example, the third etching stop layer 890 may include either aluminum nitride (AlN) or aluminum oxide (AlO). The upper interlayer insulating layer 170 may be in contact with an upper surface of the third etching stop layer 890 while being disposed on the upper surface of the third etching stop layer 890.

Although embodiments of the disclosure have been described with reference to the accompanying drawings, the disclosure is not limited to the above embodiments, but may be implemented in various different forms. A person skilled in the art may appreciate that the disclosure may be practiced in other concrete forms without changing the technical spirit or essential characteristics of the disclosure. Therefore, the embodiments as described above is not restrictive but illustrative in all respects.

What is claimed is:

1. A semiconductor device comprising:
a substrate;
an interlayer insulating layer disposed on the substrate;
an upper wiring trench disposed in the interlayer insulating layer; and
an upper wiring layer comprising:
an upper wiring barrier layer disposed along a sidewall and a bottom surface of the upper wiring trench,
an upper wiring filling layer disposed on the upper wiring barrier layer so as to fill at least a portion of an inside of the upper wiring trench, and
an upper wiring capping layer disposed on an upper surface of the upper wiring filling layer,
wherein the upper wiring capping layer includes cobalt (Co), and
wherein a volume percentage of a crystal structure having a hexagonal close-packed structure in the upper wiring capping layer is in a range of about 80% to about 100%.

2. The semiconductor device of claim 1, further comprising a first etching stop layer disposed on an upper surface of at least one of the interlayer insulating layer, the upper wiring barrier layer, or the upper wiring capping layer.

3. The semiconductor device of claim 2, further comprising a second etching stop layer in contact with the first etching stop layer on an upper surface of the first etching stop layer,
wherein a second material in the second etching stop layer is different from a first material in the first etching stop layer.

4. The semiconductor device of claim 3, further comprising a third etching stop layer in contact with the second etching stop layer on an upper surface of the second etching stop layer,
wherein a third material in the third etching stop layer is different from the second material in the second etching stop layer.

5. The semiconductor device of claim 2, further comprising an upper interlayer insulating layer in contact with an upper surface of the first etching stop layer on the upper surface of the first etching stop layer.

6. The semiconductor device of claim 1, further comprising:
a via trench disposed under the upper wiring trench inside the interlayer insulating layer; and
a via connected to the upper wiring layer, the via comprising a via barrier layer disposed along a sidewall and a bottom surface of the via trench, and
a via filling layer disposed on the via barrier layer so as to fill an inside of the via trench,
wherein a first width in a horizontal direction of the via is smaller than a second width in the horizontal direction of the upper wiring layer.

7. The semiconductor device of claim 6, wherein the upper wiring barrier layer is disposed between an upper surface of the via filling layer and a lower surface of the upper wiring filling layer.

8. The semiconductor device of claim 6, wherein an upper surface of the via filling layer is in contact with a lower surface of the upper wiring filling layer.

9. The semiconductor device of claim 1, wherein a first vertical level of an upper surface of the upper wiring capping layer is higher than a second vertical level of an upper surface of the interlayer insulating layer.

10. The semiconductor device of claim 1, wherein a sidewall of the upper wiring capping layer is in contact with the upper wiring barrier layer.

11. A semiconductor device comprising:
a substrate;
an interlayer insulating layer disposed on the substrate;
a via trench disposed inside the interlayer insulating layer;
a via comprising a via barrier layer disposed along a sidewall and a bottom surface of the via trench,
a via filling layer disposed on the via barrier layer so as to fill an inside of the via trench;
an upper wiring trench disposed on the via trench in the interlayer insulating layer; and
an upper wiring layer comprising an upper wiring barrier layer disposed along a sidewall and a bottom surface of the upper wiring trench, an upper wiring filling layer disposed on the upper wiring barrier layer so as to fill at least a portion of an inside of the upper wiring trench, and an upper wiring capping layer disposed on an upper surface of the upper wiring filling layer,
wherein a first width in a horizontal direction of the via is smaller than a second width in the horizontal direction of the upper wiring layer, and
wherein a volume percentage of a crystal structure having a hexagonal close-packed structure contained in the upper wiring capping layer is in a range of about 80% to about 100%.

12. The semiconductor device of claim 11, wherein the upper wiring capping layer contains cobalt (Co).

13. The semiconductor device of claim 11, further comprising an etching stop layer disposed on an upper surface of at least one of the interlayer insulating layer, the upper wiring barrier layer and the upper wiring capping layer.

14. The semiconductor device of claim 11, wherein the upper wiring barrier layer is disposed between an upper surface of the via filling layer and a lower surface of the upper wiring filling layer.

15. The semiconductor device of claim 11, wherein a first vertical level of an upper surface of the upper wiring capping layer is higher than a second vertical level of an upper surface of the interlayer insulating layer.

16. The semiconductor device of claim 11, further comprising:
a lower interlayer insulating layer disposed between an upper surface of the substrate and a lower surface of the interlayer insulating layer; and
a lower wiring layer disposed inside the lower interlayer insulating layer,
wherein the lower wiring layer is connected to the via.

17. A semiconductor device comprising:
a substrate;
an interlayer insulating layer disposed on the substrate;
an upper wiring trench disposed in the interlayer insulating layer;
an upper wiring layer comprising an upper wiring barrier layer disposed along a sidewall and a bottom surface of the upper wiring trench,
an upper wiring filling layer disposed on the upper wiring barrier layer so as to fill at least a portion of an inside of the upper wiring trench,
an upper wiring capping layer disposed on an upper surface of the upper wiring filling layer; and
a first etching stop layer disposed on an upper surface of at least one of the interlayer insulating layer, the upper wiring barrier layer and the upper wiring capping layer,
wherein a first vertical level of the upper surface of the upper wiring capping layer is higher than a second vertical level of the upper surface of the interlayer insulating layer,
wherein a volume percentage of a crystal structure having a hexagonal close-packed structure contained in the upper wiring capping layer is in a range of about 80% to about 100%.

18. The semiconductor device of claim 17, wherein the first etching stop layer is in contact with a sidewall of the upper wiring capping layer.

19. The semiconductor device of claim 17, further comprising an upper interlayer insulating layer in contact with an upper surface of the first etching stop layer on the upper surface of the first etching stop layer.

20. The semiconductor device of claim 17, further comprising a second etching stop layer in contact with the first etching stop layer on an upper surface of the first etching stop layer,
wherein a second material in the second etching stop layer is different from a first material in the first etching stop layer.
